(19) United States
(12) Patent Application Publication
(10) Pub. No.: US 2026/0104726 A1
(43) Pub. Date: Apr. 16, 2026

(54) APPARATUS FOR GENERATING A PVT-ROBUST REFERENCE CURRENT

(71) Applicant: KOREA ADVANCED INSTITUTE OF SCIENCE AND TECHNOLOGY, Daejeon (KR)

(72) Inventors: SeongHwan Cho, Daejeon (KR); Pangi Park, Daejeon (KR)

(73) Assignee: KOREA ADVANCED INSTITUTE OF SCIENCE AND TECHNOLOGY, Daejeon (KR)

(21) Appl. No.: 19/097,546

(22) Filed: Apr. 1, 2025

(30) Foreign Application Priority Data
Oct. 11, 2024 (KR) 10-2024-0138912

(51) Int. Cl. G05F 3/26

(52) U.S. Cl. CPC G05F 3/262

(57) ABSTRACT

An apparatus for generating a PVT (Process, Voltage, Temperature)-robust reference current is provided. The apparatus includes: a reference current mirror having a 1-st transistor, a 2-nd transistor, and a 3-rd transistor; a current-controlling voltage generating part configured to generate a current-controlling voltage which allows a reference current to be corresponding to a specific temperature coefficient; a reference voltage generating part for adjusting the temperature coefficient configured to generate a reference voltage for adjusting the temperature coefficient; a PTAT-characteristics current acquiring part allowing the reference current to have PTAT-characteristics; a CTAT-characteristics current acquiring part allowing the reference current to have CTAT-characteristics; and a comparison voltage generating part for adjusting the temperature coefficient configured to generate a comparison voltage to be used for adjusting the temperature coefficient of the reference current through an internal division of a 1-st voltage and a 2-nd voltage by using a specific weight value.

### CROSS-REFERENCE TO RELATED APPLICATIONS

This present application claims the benefit of the earlier filing date of Korean non-provisional patent application No. 10-2024-0138912, filed on Oct. 11, 2024, the entire contents of which being incorporated herein by reference.

### TECHNICAL FIELD

The present disclosure relates to an apparatus for generating a PVT (Process, Voltage, Temperature)-robust reference current.

### BACKGROUND

Electronic circuits, such as semiconductor memory circuits, generally require a reference current or reference voltage having a constant level. Further, a reference current generating circuit or reference voltage generating circuit is used as a circuit for generating the reference voltage and the reference current.

Specifically, the reference current generating circuit always needs to generate a current having the constant level regardless of the voltage level and needs to be able to supply a desired level of current to a circuit that a designer intends to use.

Further, it is preferable that the reference current generating circuit maintains the current at the constant level regardless of a change in external power supply voltage, a change in temperature, or a change in process, in order to secure a reliability of a semiconductor device in particular.

For generating a reference current, which is independent of such the PVT (Process, Voltage, Temperature) changes, a current-summation method or a division-based method has been used as the conventional prior art. Herein, the current-summation method may perform a weighted sum of two different currents having PTAT (Proportional To Absolute Temperature)-characteristics and CTAT (Complementary To Absolute Temperature)-characteristics respectively, and the division-based method may generate a compensation voltage having a same temperature coefficient (TC) such as a resistor and then apply the compensation voltage to both ends of the resistor through a voltage-current converting circuit.

According to the current-summation method, since the PTAT-characteristics current and the CTAT-characteristics current have not only a first-order temperature coefficient but also a second-order temperature coefficient, a curvature would occur in the reference current that is the weighted sum of the PTAT-characteristics current and the CTAT-characteristics current. Further, the influence of these high-order temperature coefficients becomes greater as the temperature range widens, resulting in a rapid deterioration of the temperature stability of the reference current. In addition, large changes occur in values of each of the PATA-characteristics current and the CTAT-characteristics current due to the changes in the device characteristics of the resistor according to the change in the process, leading to a large change in the reference current which is the weighted sum of the PTAT-characteristics current and the CTAT-characteristics current. Therefore, in order to compensate for the influence of the high-order temperature coefficients and for the large change in the reference current according to the device characteristics of the resistor, three-point trimming can be applied, but this approach brings disadvantages related to costs of time and space.

Further, according to the division-based method, since the temperature dependency of the resistor and the voltage at both ends of the resistor are the same, the temperature dependency of the reference current which is a ratio of the voltage to the resistor does not appear. And, since the temperature coefficient of the resistor is less affected by the change in the process, the temperature coefficient of the reference current generated by using the division-based method is less affected by the change in the process compared to the temperature coefficient of the reference current generated by using the current-summation method. However, the division-based method still has the problem of the curvature issue caused by the second-order temperature coefficient of the resistor and the compensation voltage, thus it still has a limitation in the temperature stability over a wide range of temperatures.

Accordingly, it is necessary to invent an advanced apparatus for generating the PVT-robust reference current over the wide range of temperatures.

### SUMMARY

It is an object of the present disclosure to solve all the aforementioned problems.

It is another object of the present disclosure to generate a PVT-robust reference current over a wide range of temperatures.

It is still another object of the present disclosure to provide a PVT-robust reference current source capable of adjusting a temperature coefficient.

It is still yet another object of the present disclosure to generate each of the reference currents whose temperature coefficients have been adjusted for each of sub-ranges divided within a full range of temperatures.

It is still yet another object of the present disclosure to divide the full range of temperatures into the sub-ranges without using a temperature sensor.

In accordance with one aspect of the present disclosure, there is provided an apparatus for generating a PVT (Process, Voltage, Temperature)-robust reference current comprising: a reference current mirror including: a 1-st transistor, a 2-nd transistor, and a 3-rd transistor, wherein each of 1-st terminals of each of the 1-st transistor, the 2-nd transistor, and the 3-rd transistor is connected to a supply voltage providing part, wherein each of controlling terminals of each of the 1-st transistor, the 2-nd transistor, and the 3-rd transistor is provided with a current-controlling voltage, and wherein each of 2-nd terminals of each of the 1-st transistor, the 2-nd transistor, and the 3-rd transistor provides a reference current to each of a 1-st node, a 2-nd node, and a 3-rd node, wherein the reference current is generated according to the current-controlling voltage; a current-controlling voltage generating part configured to generate the current-controlling voltage which allows the reference current to be corresponding to a specific temperature coefficient according to conditions of each of a reference voltage for adjusting a temperature coefficient fed through a 1-st input end of the current-controlling voltage generating part and a comparison voltage for adjusting the temperature coefficient fed through a 2-nd input end of the current-controlling voltage generating part; a reference voltage generating part for adjusting the temperature coefficient configured to generate the reference voltage for adjusting the temperature coefficient, wherein the reference voltage is used for adjusting the temperature coefficient of the reference current according to the reference current fed through the 1-nd node; a PTAT (Proportion To Absolute Temperature)-characteristics current acquiring part, which is connected to the 2-nd node, for allowing the reference current to have PTAT-characteristics in case the 2-nd node is connected to the 2-nd input end of the current-controlling voltage generating part; a CTAT (Complementary To Absolute Temperature)-characteristics current acquiring part, which is connected to the 3-rd node, for allowing the reference current to have CTAT-characteristics in case the 3-rd node is connected to the 2-nd input end of the current-controlling voltage generating part; and a comparison voltage generating part for adjusting the temperature coefficient, which is connected between the 2-nd node and the 3-rd node, wherein the comparison voltage generating part is configured to generate the comparison voltage to be used for adjusting the temperature coefficient of the reference current through an internal division of a 1-st voltage and a 2-nd voltage by using a specific weight value, wherein the specific weight value corresponding to the specific temperature coefficient of the reference current is determined by referring to the 1-st voltage of the 2-nd node caused by the PTAT-characteristics current acquiring part and the 2-nd voltage of the 3-rd node caused by the CTAT-characteristics current acquiring part.

As one example, on condition that (i) a full range of temperatures to be used has been divided into a 1-st sub-range and a 2-nd sub-range based on a specific temperature which is a temperature for allowing each of reference currents to have a same value over all of temperature coefficients, wherein the specific temperature is determined according to a ratio of a 1-st resistance value of a 1-st resistor included in the PTAT-characteristics current acquiring part and a 2-nd resistance value of a 2-nd resistor included in the CTAT-characteristics current acquiring part and (ii) a 1-st temperature coefficient and a 2-nd temperature coefficient have been determined, wherein the 1-st temperature coefficient makes a current-fluctuation ratio of the reference current according to a temperature change within the 1-st sub-range be the smallest, and wherein the 2-nd temperature coefficient makes current-fluctuation ratio of the reference current according to a temperature change within the 2-nd sub-range be the smallest, the comparison voltage generating part for adjusting the temperature coefficient (i) selects a specific sub-range between the 1-st sub-range and the 2-nd sub-range by referring to a difference between the 1-st voltage and the 2-nd voltage, and (ii) performs the internal division of the 1-st voltage and the 2-nd voltage by using the specific weight value corresponding to the specific temperature coefficient selected between the 1-st temperature coefficient and the 2-nd temperature coefficient, wherein the specific temperature coefficient is determined according to the specific sub-range.

As one example, the comparison voltage generating part for adjusting the temperature coefficient includes: a comparator configured to output a control signal by comparing the 1-st voltage with the 2-nd voltage; a multiplexer configured to output the specific weight value selected between a 1-st weight value and a 2-nd weight value according to the control signal, wherein the 1-st weight value is set to be corresponding to the 1-st temperature coefficient and the 2-nd weight value is set to be corresponding to the 2-nd temperature coefficient; a row-column decoder configured to output a row-address signal and a column-address signal by referring to the specific weight value; and an RDAC (resistive digital-to-analog converter) configured to output the comparison voltage used for adjusting the temperature coefficient of the reference current through the internal division of the 1-st voltage and the 2-nd voltage by using the specific weight value between the 2-nd node and the 3-rd node, according to the row-address signal and the column-address signal.

As one example, the comparator has hysteresis characteristics.

As one example, the apparatus for generating the PVT-robust reference current further comprises: a reference current-outputting part which includes a 4-th transistor, wherein a 1-st terminal of the 4-th transistor is connected to the supply voltage providing part, wherein the reference current generated by the reference current mirror is copied according to the current-controlling voltage fed to a controlling terminal of the 4-th transistor, and wherein the copied-reference current is outputted through a 2-nd terminal of the 4-th transistor.

As one example, the reference voltage generating part for adjusting the temperature coefficient includes a 5-th transistor, wherein (i) a 1-st terminal of the 5-th transistor is connected to the 1-st node and (ii) a controlling terminal of the 5-th transistor and a 2-nd terminal of the 5-th transistor are connected to a ground line.

As one example, the 5-th transistor is a bipolar transistor, wherein (i) an emitter terminal of the 5-th transistor is connected to the 1-st node and (ii) a base terminal of the 5-th transistor and a collector terminal of the 5-th transistor are connected to the ground line.

As one example, the PTAT-characteristics current acquiring part includes a 1-st resistor and a 6-th transistor, wherein one end of the 1-st resistor is connected to the 2-nd node, wherein a 1-st terminal of the 6-th transistor is connected to an opposite end of the 1-st resistor, and wherein a controlling terminal of the 6-th transistor and a 2-nd terminal of the 6-th transistor are connected to a ground line.

As one example, the 6-th transistor is a bipolar transistor, wherein (i) an emitter terminal of the 6-th transistor is connected to the opposite end of the 1-st resistor and (ii) a base terminal of the 6-th transistor and a collector terminal of the 6-th transistor are connected to the ground line.

As one example, the CTAT-characteristics current acquiring part includes a 2-nd resistor, wherein one end of the 2-nd resistor is connected to the 3-rd node and an opposite end of the 2-nd resistor is connected to a ground line.

As one example, the current-controlling voltage generating part includes an amplifier, wherein the reference voltage for adjusting the temperature coefficient is inputted into an inverting end of the amplifier and the comparison voltage for adjusting the temperature coefficient is inputted into a non-inverting end of the amplifier, and wherein an output end of the amplifier is connected to each of the controlling terminals of each of the 1-st transistor, the 2-nd transistor, and the 3-rd transistor.

As one example, each of the 1-st transistor, the 2-nd transistor, and the 3-rd transistor is a PMOS transistor, wherein each of gate terminals of each of the 1-st transistor, the 2-nd transistor, and the 3-rd transistor is connected to an output end of the current-controlling voltage generating part, wherein each of source terminals of each of the 1-st transistor, the 2-nd transistor, and the 3-rd transistor is connected to the supply voltage providing part, and wherein each of drain terminals of each of the 1-st transistor, the 2-nd transistor, and the 3-rd transistor is connected to each of the 1-st node, the 2-nd node, and the 3-rd node.

### BRIEF DESCRIPTION OF THE DRAWINGS

The above and other objects and features of the present disclosure will become apparent from the following description of preferred embodiments given in conjunction with the accompanying drawings.

The following drawings to be used to explain example embodiments of the present disclosure are only part of example embodiments of the present disclosure and other drawings can be obtained based on the drawings by those skilled in the art of the present disclosure without inventive work.

FIG. 1 is a drawing schematically illustrating an apparatus for generating a PVT-robust reference current in accordance with one example embodiment of the present disclosure.

FIG. 2 is a drawing schematically illustrating a comparison voltage generating part for adjusting a temperature coefficient in the apparatus for generating the PVT-robust reference current in accordance with one example embodiment of the present disclosure.

FIG. 3 is a drawing schematically illustrating an RDAC of the comparison voltage generating part for adjusting the temperature coefficient illustrated in FIG. 2.

FIG. 4 is a drawing schematically illustrating a state of generating the reference current in the apparatus for generating the PVT-robust reference current in accordance with one example embodiment of the present disclosure.

FIG. 5 is a drawing schematically illustrating a relationship between a temperature and a reference current according to each of temperature coefficients in the apparatus for generating the PVT-robust reference current in accordance with one example embodiment of the present disclosure.

FIG. 6 is a drawing schematically illustrating a state of determining a midpoint in the apparatus for generating the PVT-robust reference current in accordance with one example embodiment of the present disclosure.

FIG. 7 is a drawing schematically illustrating a state of generating each of reference currents corresponding to each of temperature coefficients according to sub-ranges in the apparatus for generating the PVT-robust reference current in accordance with one example embodiment of the present disclosure.

FIG. 8 is a drawing schematically illustrating a circuit diagram in the apparatus for generating the PVT-robust reference current in accordance with one example embodiment of the present disclosure.

FIG. 9 is a drawing schematically illustrating a relationship between the reference current and the temperature according to each of weight values in the apparatus for generating the PVT-robust reference current in accordance with one example embodiment of the present disclosure.

FIG. 10 is a drawing schematically illustrating a state of generating each of the reference currents corresponding to each of the weight values according to the sub-ranges in the apparatus for generating the PVT-robust reference current in accordance with one example embodiment of the present disclosure.

Like reference symbols in the various drawings indicate like elements.

### DETAILED DESCRIPTION OF ILLUSTRATIVE EMBODIMENTS

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the present invention, although different, are not necessarily mutually exclusive. For example, a particular feature, structure, or characteristic described herein in connection with one embodiment may be implemented within other embodiments without departing from the spirit and scope of the present invention.

In addition, it is to be understood that the position or arrangement of individual elements within each disclosed embodiment may be modified without departing from the spirit and scope of the present invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

To allow those skilled in the art to carry out the present invention easily, the example embodiments of the present invention by referring to attached diagrams will be explained in detail as shown below.

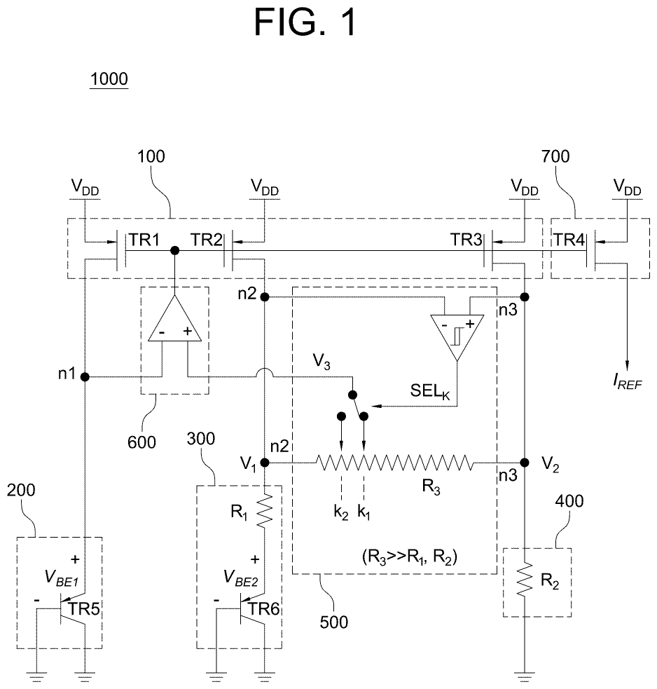

FIG. 1 is a drawing schematically illustrating an apparatus for generating a PVT-robust reference current in accordance with one example embodiment of the present disclosure. By referring to FIG. 1, the apparatus 1000 for generating the PVT-robust reference current may include a reference current mirror 100, a reference voltage generating part 200 for adjusting a temperature coefficient, a PTAT (Proportion To Absolute Temperature)-characteristics current acquiring part 300, a CTAT (Complementary To Absolute Temperature)-characteristics current acquiring part 400, a comparison voltage generating part 500 for adjusting the temperature coefficient, and a current-controlling voltage generating part 600. And, the apparatus 1000 for generating the PVT-robust reference current may further include a reference current-outputting part 700.

First, the reference current mirror 100 may have a 1-st transistor TR1, a 2-nd transistor TR2, and a 3-rd transistor TR3. Herein, (i) each of 1-st terminals of each of the 1-st transistor TR1, the 2-nd transistor TR2, and the 3-rd transistor TR3 can be connected to a supply voltage providing part V_{DD}, (ii) each of controlling terminals of each of the 1-st transistor TR1, the 2-nd transistor TR2, and the 3-rd transistor TR3 can be provided with a current-controlling voltage, and (iii) each of 2-nd terminals of each of the 1-st transistor TR1, the 2-nd transistor TR2, and the 3-rd transistor TR3 can provide a reference current I_{REF} to each of a 1-st node n1, a 2-nd node n2, and a 3-rd node n3. Herein, the reference current I_{REF} can be generated according to the current-controlling voltage.

In this case, each of the 1-st transistor TR1, the 2-nd transistor TR2, and the 3-rd transistor TR3 may be a PMOS transistor. Herein, (i) each of gate terminals of each of the 1-st transistor TR1, the 2-nd transistor TR2, and the 3-rd transistor TR3 can be connected to an output end of the current-controlling voltage generating part 600, (ii) each of source terminals of each of the 1-st transistor TR1, the 2-nd transistor TR2, and the 3-rd transistor TR3 can be connected to the supply voltage providing part V_{DD}, and (iii) each of drain terminals of each of the 1-st transistor TR1, the 2-nd transistor TR2, and the 3-rd transistor TR3 can be connected to each of the 1-st node n1, the 2-nd node n2, and the 3-rd node n3.

Meanwhile, the apparatus 1000 for generating the PVT-robust reference current may further include the reference current-outputting part 700. Herein, the reference current-outputting part 700 is able to copy the reference current I_{REF} generated by the reference current mirror 100 according to the current-controlling voltage, and then it is able to output the copied-reference current. Further, the reference current-outputting part 700 may have a 4-th transistor TR4. Herein, a 1-st terminal of the 4-th transistor TR4 can be connected to the supply voltage providing part V_{DD}. In this case, the 4-th transistor TR4 may be configured to be a semiconductor transistor having a same size as the 1-st transistor TR1, the 2-nd transistor TR2, and the 3-rd transistor TR3, and it may output the same reference current I_{REF} by forming a current mirror. Further, the 4-th transistor TR4 may be a PMOS transistor. Herein, (i) a gate terminal of the 4-th transistor TR4 can be connected to the output end of the current-controlling voltage generating part 600, (ii) a source terminal of the 4-th transistor TR4 can be connected to the supply voltage providing part V_{DD}, and (iii) the reference current I_{REF} can be outputted through a drain terminal of the 4-th transistor TR4.

Next, the current-controlling voltage generating part 600 may generate the current-controlling voltage which allows the reference current I_{REF} to be corresponding to a specific temperature coefficient according to conditions of each of a reference voltage V_{BE1} for adjusting the temperature coefficient fed through a 1-st input end of the current-controlling voltage generating part 600 and a comparison voltage V₃ for adjusting the temperature coefficient fed through a 2-nd input end of the current-controlling voltage generating part 600.

Herein, the current-controlling voltage generating part 600 may have an amplifier. In this case, (i) the reference voltage V_{BE1} for adjusting the temperature coefficient can be inputted into an inverting end of the amplifier, (ii) the comparison voltage V₃ for adjusting the temperature coefficient can be inputted into a non-inverting end of the amplifier, and (iii) an output end of the amplifier can be connected to each of the controlling terminals of each of the 1-st transistor TR1, the 2-nd transistor TR2, and the 3-rd transistor TR3.

Next, the reference voltage generating part 200 for adjusting the temperature coefficient can be connected to the 1-st node n1, and it may generate the reference voltage V_{BE1} for adjusting the temperature coefficient. Herein, the reference voltage V_{BE1} is used for adjusting the temperature coefficient of the reference current I_{REF} according to the reference current I_{REF} fed through the 1-nd node n1.

Herein, the reference voltage generating part 200 for adjusting the temperature coefficient may have a 5-th transistor TR5.

In addition, the 5-th transistor TR5 may be configured to be a semiconductor transistor. Herein, (i) a 1-st terminal of the 5-th transistor TR5 can be connected to the 1-st node n1 and (ii) a controlling terminal of the 5-th transistor TR5 and a 2-nd terminal of the 5-th transistor TR5 can be connected to a ground line.

For example, the 5-th transistor TR5 may be a bipolar transistor. Herein, (i) an emitter terminal of the 5-th transistor TR5 can be connected to the 1-st node n1 and (ii) a base terminal of the 5-th transistor TR5 and a collector terminal of the 5-th transistor TR5 can be connected to the ground line.

Next, the PTAT-characteristics current acquiring part 300 can be connected to the 2-nd node n2, and it may allow the reference current I_{REF} to have PTAT-characteristics in case the 2-nd node n2 is connected to the 2-nd input end of the current-controlling voltage generating part 600.

Herein, the PTAT-characteristics current acquiring part 300 may have a 1-st resistor R₁ and a 6-th transistor TR6. In this case, (i) one end of the 1-st resistor R₁ can be connected to the 2-nd node n2, (ii) a 1-st terminal of the 6-th transistor TR6 can be connected to an opposite end of the 1-st resistor R₁, and (iii) a controlling terminal of the 6-th transistor TR6 and a 2-nd terminal of the 6-th transistor TR6 can be connected to the ground line.

For example, the 6-th transistor TR6 may be configured to be a semiconductor transistor having different sizes from that of the 5-th transistor TR5 included in the reference voltage generating part 200 for adjusting the temperature coefficient. Further, the 6-th transistor TR6 may be a bipolar transistor. Herein, (i) an emitter terminal of the 6-th transistor TR6 can be connected to the opposite end of the 1-st resistor R₁ and (ii) a base terminal of the 6-th transistor TR6 and a collector terminal of the 6-th transistor TR6 can be connected to the ground line.

Next, the CTAT-characteristics current acquiring part 400 can be connected to the 3-rd node n3, and it may allow the reference current I_{REF} to have CTAT-characteristics in case the 3-rd node n3 is connected to the 2-nd input end of the current-controlling voltage generating part 600.

Herein, the CTAT-characteristics current acquiring part 400 may have a 2-nd resistor R₂. In this case, one end of the 2-nd resistor R₂ can be connected to the 3-rd node n3 and an opposite end of the 2-nd resistor R₂ can be connected to the ground line.

Next, the comparison voltage generating part 500 for adjusting the temperature coefficient, which can be connected between the 2-nd node n2 and the 3-rd node n3, may generate the comparison voltage V₃ to be used for adjusting the temperature coefficient of the reference current I_{REF} through an internal division of a 1-st voltage V₁ and a 2-nd voltage V₂ by using a specific weight value k₁ or k₂ corresponding to the specific temperature coefficient of the reference current I_{REF}. Herein, the specific weight value k₁ or k₂ can be determined by referring to the 1-st voltage V₁ of the 2-nd node n2 caused by the PTAT-characteristics current acquiring part 300 and the 2-nd voltage V₂ of the 3-rd node n3 caused by the CTAT-characteristics current acquiring part 400.

Herein, on condition that (i) a full range of temperatures to be used has been divided into a 1-st sub-range and a 2-nd sub-range based on a specific temperature which is a temperature for allowing each of reference currents I_{REF} to have a same value over all of temperature coefficients and (ii) a 1-st temperature coefficient and a 2-nd temperature coefficient have been determined, the comparison voltage generating part 500 for adjusting the temperature coefficient can (i) select a specific sub-range between the 1-st sub-range and the 2-nd sub-range by referring to a difference between the 1-st voltage V₁ and the 2-nd voltage V₂, and (ii) perform the internal division, i.e., a weighted sum, of the 1-st voltage V₁ and the 2-nd voltage V₂ by using the specific weight value k₁ or k₂ corresponding to the specific temperature coefficient selected between the 1-st temperature coefficient and the 2-nd temperature coefficient. Herein, (i) the specific temperature coefficient can be determined according to a ratio of a 1-st resistance value of a 1-st resistor R₁ included in the PTAT-characteristics current acquiring part 300 and a 2-nd resistance value of a 2-nd resistor R₂ included in the CTAT-characteristics current acquiring part 400, (ii) the 1-st temperature coefficient can make a current-fluctuation ratio of the reference current I_{REF} according to a temperature change within the 1-st sub-range be the smallest and the 2-nd temperature coefficient can make current-fluctuation ratio of the reference current I_{REF} according to a temperature change within the 2-nd sub-range be the smallest, and (iii) the specific temperature coefficient is determined according to the specific sub-range.

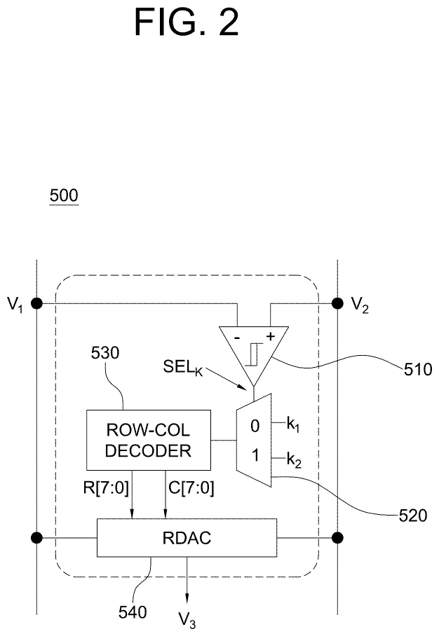

For example, by referring to FIG. 2, the comparison voltage generating part 500 for adjusting the temperature coefficient may have (i) a comparator 510 configured to output a control signal SELₖ by comparing the 1-st voltage V₁ with the 2-nd voltage V₂, (ii) a multiplexer configured to output the specific weight value selected between a 1-st weight value k₁ and a 2-nd weight value k₂ according to the control signal SELₖ of the comparator 510, (iii) a row-column decoder 530 configured to output a row-address signal and a column-address signal by referring to the specific weight value, and (iv) an RDAC (resistive digital-to-analog converter) 540 configured to output the comparison voltage V₃ used for adjusting the temperature coefficient of the reference current through the internal division of the 1-st voltage V₁ and the 2-nd voltage V₂ by using the specific weight value between the 2-nd node n2 and the 3-rd node n3, according to the row-address signal and the column-address signal. Herein, the 1-st weight value k₁ can be set to be corresponding to the 1-st temperature coefficient and the 2-nd weight value k₂ can be set to be corresponding to the 2-nd temperature coefficient. For reference, FIG. 2 is a drawing illustrating an example that the row-column decoder 530 is outputting a 3-bit row-address signal R[7:0] and a 3-bit column-address signal C[7:0].

Herein, the comparator 510 may have hysteresis characteristics in order to prevent a switching caused by noise within threshold intervals according to the difference between the 1-st voltage V₁ and the 2-nd voltage V₂.

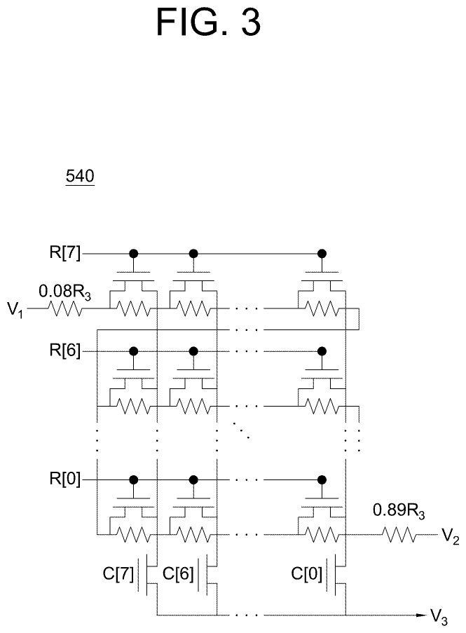

Further, for example, by referring to FIG. 3, the RDAC 540 of the comparison voltage generating part 500 for adjusting the temperature coefficient may be an N-bit folded RDAC having (i) a resistor group R₃ in which 2^{N} resistors with a same resistance value are connected in series between the 1-st voltage V₁ and the 2-nd voltage V₂, (ii) 2^{N} row-line switches enabled by the row-address signal, and (iii) N column-line switches enabled by the column-address signal. Herein, each of the 2^{N} row-line switches can be configured such that each of 1-st ends of the 2^{N} row-line switches is connected to each of one ends of the resistors, and each of the N column-line switches can be configured such that each of 1-st ends of the N column-line switches is connected to each of 2-nd ends of the row-line switches positioned at each of same column lines and each of the 2-nd ends of the N column-line switches is connected to an output line. In addition, the N-bit folded RDAC may further have an output buffer (not shown) connected to the output line. Herein, the output buffer (not shown) is configured to generate an analog output, i.e., generate the comparison voltage V₃ used for adjusting the temperature coefficient, by buffering output values outputted through the output line. However, the present disclosure is not limited thereto, the comparison voltage generating part 500 for adjusting the temperature coefficient may be implemented as various types of DACs that perform the internal division of the 1-st voltage V₁ and the 2-nd voltage V₂. For reference, FIG. 3 is a drawing schematically illustrating a 6-bit folded RDAC which is corresponding to the row-column decoder 530 that outputs the 3-bit row-address signal R[7:0] and the 3-bit column-address signal C[7:0].

Meanwhile, the current-controlling voltage generating part 600 in the apparatus 1000 for generating the PVT-robust reference current in accordance with one example embodiment of the present disclosure may adjust the reference voltage V_{BE1} for adjusting the temperature coefficient and the comparison voltage V₃ for adjusting the temperature coefficient to have a same value through negative feedback loops. Further, it may adjust each of weight values of each of the PTAT-characteristics of the reference current I_{REF} and the CTAT-characteristics of the reference current I_{REF} according to which specific weight value k, i.e., the specific weight value k of the RDAC, the comparison voltage V₃ for adjusting the temperature coefficient is determined by. Herein, the specific weight value k is used to perform the internal division of the 1-st voltage V₁ and the 2-nd voltage V₂. For example, (i) as the weight value k is adjusted such that a node of the comparison voltage V₃ for adjusting the temperature coefficient is closer to the 2-nd node n2, i.e., closer to the PTAT-characteristics current acquiring part 300, the weight value of the PTAT-characteristics of the reference current I_{REF} can be increased and (ii) as the weight value k is adjusted such that the node of the comparison voltage V₃ for adjusting the temperature coefficient is closer to the 3-rd node n3, i.e., closer to the CTAT-characteristics current acquiring part 400, the weight value of the CTAT-characteristics of the reference current I_{REF} can be increased.

The apparatus for generating the PVT-robust reference current in accordance with one example embodiment of the present disclosure is explained in more detail as below.

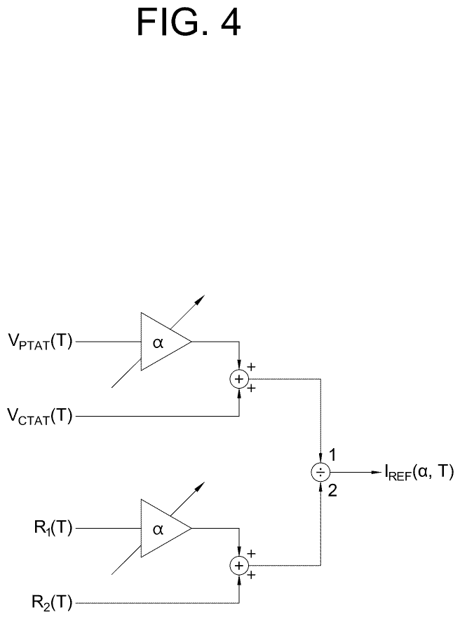

FIG. 4 is a drawing schematically illustrating a state of generating the reference current in the apparatus for generating the PVT-robust reference current in accordance with one example embodiment of the present disclosure. By referring to FIG. 4, the reference current I_{REF}(α,T) adjusted by the temperature coefficient α at a temperature of T can be represented as Formula 1 as follows:

$${I}_{REF} ( α , T ) = \frac{α \cdot {V}_{PTAT} ( T ) + {V}_{CTAT} ( T )}{α \cdot {R}_{1} ( T ) + {R}_{2} ( T )} \qquad [ Formula 1 ]$$

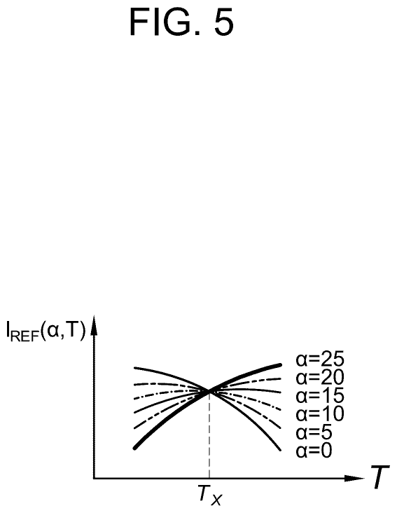

Further, FIG. 5 is a graph illustrating a relationship between the temperature T and the reference current I_{REF}(α,T) from each of different temperature coefficients according to Formula 1. By referring to FIG. 5, it can be seen that each of current values of each of the reference currents according to different temperature coefficients has a same value at a specific temperature Tₓ. That is, it can be seen that each of the reference currents for each of the different temperature coefficients intersects at a point regardless of the temperature coefficient α. And the specific temperature Tₓ, which is a temperature corresponding to the point of intersection, can be defined as a midpoint.

To explain this in more detail, Formula 1 may be represented as Formula 2 as follows:

$${I}_{REF} ( α , T ) = \frac{{V}_{PTAT} ( T ) \cdot ( α + \frac{{V}_{CTAT} ( T )}{{V}_{PTAT} ( T )} )}{{R}_{1} ( T ) \cdot ( α + \frac{{R}_{2} ( T )}{{R}_{1} ( T )} )} \qquad [ Formula 2 ]$$

In Formula 2, the reference current irrelevant to the temperature coefficient α at the specific temperature Tₓ must satisfy Formula 3 below:

$$\frac{{V}_{CTAT} ( {T}_{x} )}{{V}_{PTAT} ( {T}_{x} )} = \frac{{R}_{2} ( {T}_{x} )}{{R}_{1} ( {T}_{x} )} \qquad [ Formula 3 ]$$

And, the reference current irrelevant to the temperature coefficient α at the specific temperature Tₓ can be represented as Formula 4 as follows:

$${I}_{REF} ( α , {T}_{x} ) = \frac{{V}_{PTAT} ( {T}_{x} )}{{R}_{1} ( {T}_{x} )} = \frac{{V}_{CTAT} ( {T}_{x} )}{{R}_{2} ( {T}_{x} )} \qquad [ Formula 4 ]$$

Meanwhile,

$$\frac{{R}_{2} ( {T}_{x} )}{{R}_{1} ( {T}_{x} )}$$

described in Formula 3 may have a same value within the full range of temperatures since the R₁ and the R₂ are of the same type, that is, the R₁ and the R₂ have the same temperature coefficient.

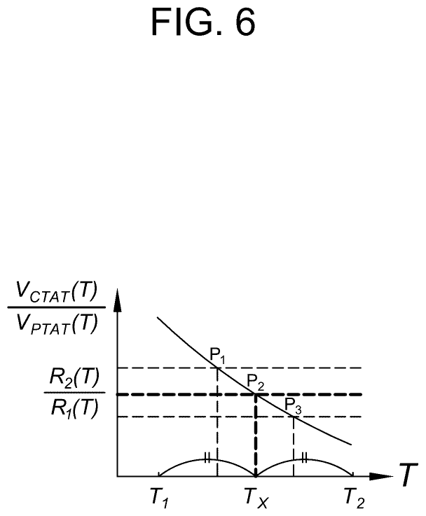

Therefore, by referring to FIG. 6, on condition that a range of temperature to be used is determined as from a temperature T₁ to a temperature T₂, a specific point P₂ for dividing a full range of from the temperature T₁ to the temperature T₂ into two sub-ranges can be determined as the midpoint Tₓ by adjusting the

$$\frac{{R}_{2}}{{R}_{1}}$$

Herein, the specific point P₂ may be selected among a plurality of points such as P₁, P₂, and P₃ satisfying Formula 3 above within the full range of from the temperature T₁ to the temperature T₂. Further, the range of from the temperature T₁ to the temperature Tₓ and the range of from the temperature Tₓ to the temperature T₂ may be adjusted to have a same size or similar sizes.

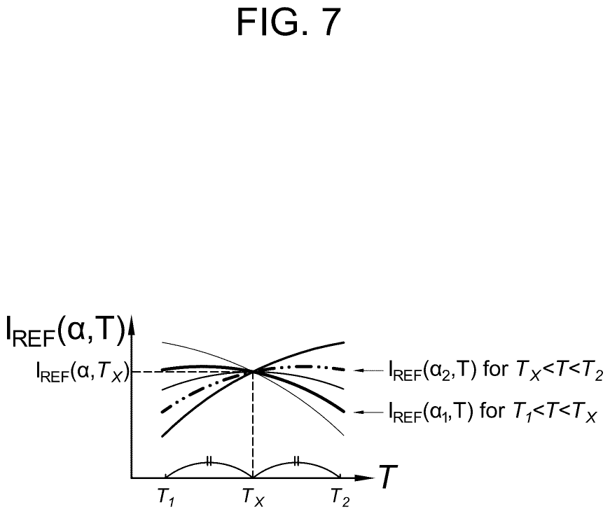

Further, by referring to FIG. 7, the apparatus 1000 for generating the PVT-robust reference current may provide the PVT-robust reference current over a wide range of temperatures by using a reference current I_{REF}(α₁,T) according to a 1-st temperature coefficient α₁ and a reference current I_{REF}(α₂, T) according to a 2-nd temperature coefficient α₂. Herein, the 1-st temperature coefficient α₁ makes a current-fluctuation ratio of the reference current according to a temperature change within the sub-range of from the temperature T₁ to the temperature Tₓ be the smallest, and the 2-nd temperature coefficient α₂ makes a current-fluctuation ratio of the reference current according to a temperature change within the sub-range of from the temperature Tₓ to the temperature T₂ be the smallest.

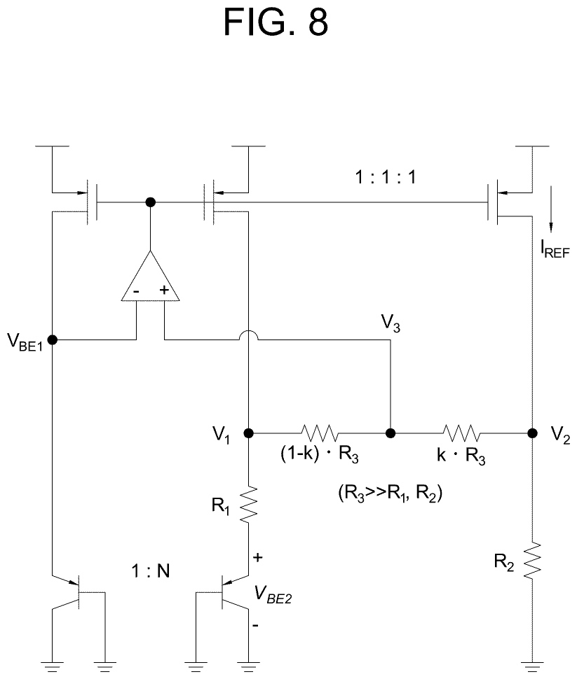

Meanwhile, FIG. 8 is a drawing schematically illustrating a circuit diagram of the apparatus for generating the PVT-robust reference current illustrated in FIG. 1.

By referring to FIG. 8, the reference current I_{REF} can be (i) the CTAT current in case a “k” is “0”, (ii) the PTAT current in case the “k” is “1”, and (iii) a summed current which is acquired by adding the CTAT current and the PTAT current in case the “k” is between “0” and “1”.

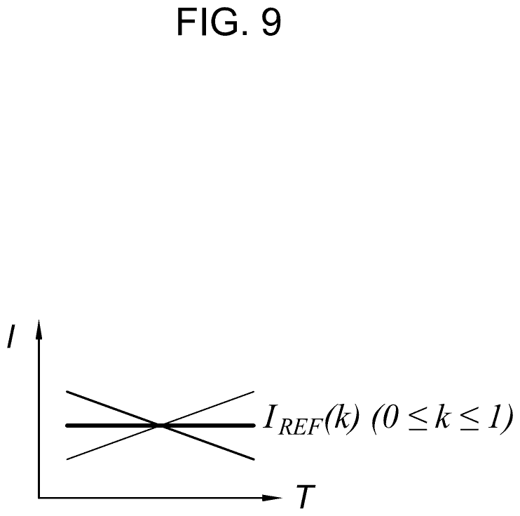

Herein, a relationship between the reference current and the temperature according to each of the “k” may be illustrated as FIG. 9, and it can be similar to the relationship between the reference current and the temperature according to each of the temperature coefficients illustrated in FIG. 5.

Meanwhile, V₁, V₂, and V₃ illustrated in FIG. 8 may be represented as Formula 5 as below. Herein, R₃ may have a larger resistance value than R₁ and R₂, and thus an effect of the current passing through R₃ can be small enough to be ignored.

$${V}_{1} = {V}_{BE 2} + {I}_{REF} \cdot {R}_{1} \qquad [ Formula 5 ]$$

$${V}_{2} = {I}_{REF} \cdot {R}_{2}$$

$${V}_{3} = k \cdot {V}_{1} + ( 1 - k ) \cdot {V}_{2} = {V}_{BE 1}$$

Further, in case the reference current I_{REF} is calculated as above, the reference current I_{REF} described in Formula 5 can be represented as Formula 6 follows:

$${I}_{REF} = \frac{\frac{k}{1 - k} \cdot {ΔV}_{BE} + {V}_{BE}}{\frac{k}{1 - k} \cdot {R}_{1} + {R}_{2}} \qquad [ Formula 6 ]$$

In formula 6, ΔV_{BE} may denote V_{BE1}−V_{BE2} and V_{BE} may denote V_{BE1}.

Herein, by comparing Formula 1 with Formula 6, it can be seen that (i) the temperature coefficient α described in Formula 1 corresponds to

$$\frac{k}{1 - k}$$

described in Formula 6, (ii) V_{PTAT} described in Formula 1 corresponds to ΔV_{BE} described in Formula 6, and (iii) V_{CTAT} described in Formula 1 corresponds to V_{BE} described in Formula 6.

By referring back to FIG. 1, the reference current according to the weight value k used to perform the internal division of the 1-st voltage V₁ and the 2-nd voltage V₂ may be represented as Formula 7 below. For reference, Formula 7 is acquired by using Formula 6. Herein, the weight value k corresponds to the temperature coefficient α.

$${I}_{REF} ( k , T ) = \frac{k \cdot {ΔV}_{BE} ( T ) + ( 1 - k ) \cdot {V}_{BE} ( T )}{k \cdot {R}_{1} ( T ) + ( 1 - k ) \cdot {R}_{2} ( T )} \qquad [ Formula 7 ]$$

Further, as can be seen from the description regarding FIG. 4, the specific temperature Tₓ may be determined as the midpoint for dividing the full range of temperatures into the two sub-ranges by adjusting

$$\frac{{R}_{2}}{{R}_{1}}$$

Herein, the specific temperature Tₓ is the temperature at which each of the reference currents has the same current value regardless of each of the weight values k corresponding to each of temperature coefficients.

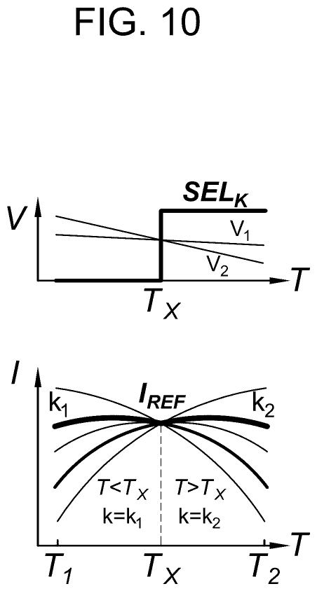

That is, further by referring to FIG. 10, a point at which each of the reference currents corresponding to each of the weight values intersects with one another according to the adjusted

$$\frac{{R}_{2}}{{R}_{1}}$$

value within the range of from the temperature T₁ to the temperature T₂ may be determined as the midpoint Tₓ.

Further, the full range of temperatures, i.e., the range of from the temperature T₁ to the temperature T₂, may be divided into the 1-st sub-range and the 2-nd sub-range based on the midpoint Tₓ. Herein, the 1-st sub-range is the range of from the temperature T₁ to the temperature Tₓ and the 2-nd sub-range is the range of from the temperature Tₓ to the temperature T₂.

In addition, the 1-st weight value k₁ corresponding to the 1-st temperature coefficient α₁ and the 2-nd weight value k₂ corresponding to the 2-nd temperature coefficient α₂ may be determined. Herein, (i) the 1-st temperature coefficient α₁ may make the current-fluctuation ratio of the reference current according to the temperature change within the 1-st sub-range, i.e., the range of from the temperature T₁ to the temperature Tₓ, be the smallest and (ii) the 2-nd temperature coefficient α₂ may make the current-fluctuation ratio of the reference current according to the temperature change within the 2-nd sub-range, i.e., the range of from the temperature Tₓ to the temperature T₂, be the smallest.

In this case, the reference current I_{REF} may not be affected by the weight value k at the midpoint Tₓ, and the 1-st voltage V₁, the 2-nd voltage V₂, the comparison voltage V₃ for adjusting the temperature coefficient, and the reference voltage V_{BE1}(=V_{BE}) for adjusting the temperature coefficient may have a same voltage value.

Accordingly, based on the midpoint Tₓ, the specific sub-range may be selected between the 1-st sub-range and the 2-nd sub-range by comparing the 1-st voltage V₁ with the 2-nd voltage V₂ without measuring the temperature directly.

That is, as can be seen from Formula 5, although the 1-st resistor R₁ with the 1-st voltage V₁ and the 2-nd resistor R₂ with the 2-nd voltage V₂ have the same temperature coefficient, since a voltage V_{BE2} having CTAT-characteristics is added to the 1-st voltage V₁, the 1-st voltage V₁ and the 2-nd voltage V₂ have the different temperature coefficients. Accordingly, the 1-st voltage V₁ and the 2-nd voltage V₂ may be the same at the midpoint Tₓ, but (i) the 1-st voltage V₁ may be higher than the 2-nd voltage V₂ within the 1-st sub-range, i.e., the range of from the temperature T₁ to the temperature Tₓ, and (ii) the 1-st voltage V₁ may be lower than the 2-nd voltage V₂ within the 2-nd sub-range, i.e., the range of from the temperature Tₓ to the temperature T₂.

Accordingly, (i) in case the 1-st voltage V₁ is greater than the 2-nd voltage V₂, the comparison voltage generating part 500 for adjusting the temperature coefficient may select the 1-st sub-range, perform the internal division of the 1-st voltage V₁ and the 2-nd voltage V₂ by using the predetermined 1-st weight value k₁, and thus generate the comparison voltage V₃ for adjusting the temperature coefficient and (ii) in case the 1-st voltage V₁ is lower than the 2-nd voltage V₂, the comparison voltage generating part 500 for adjusting the temperature coefficient may select the 2-nd sub-range, perform the internal division of the 1-st voltage V₁ and the 2-nd voltage V₂ by using the predetermined 2-nd weight value k₂, and thus generate the comparison voltage V₃ for adjusting the temperature coefficient.

The present disclosure has an effect of generating the PVT-robust reference current over the wide range of temperatures.

The present disclosure has another effect of providing a PVT-robust reference current source capable of adjusting the temperature coefficient.

The present disclosure has still another effect of generating each of the reference currents whose temperature coefficient have been adjusted for each of sub-ranges divided within a full range of temperatures.

The present disclosure has still yet another effect of dividing the full range of temperatures into the sub-ranges without using a temperature sensor.

As seen above, the present disclosure has been explained by specific matters such as detailed components, limited embodiments, and drawings. They have been provided only to help more general understanding of the present disclosure. It, however, will be understood by those skilled in the art that various changes and modification may be made from the description without departing from the spirit and scope of the disclosure as defined in the following claims.

Accordingly, the thought of the present disclosure must not be confined to the explained embodiments, and the following patent claims as well as everything including variations equal or equivalent to the patent claims pertain to the category of the thought of the present disclosure.

What is claimed is:

1. An apparatus for generating a PVT (Process, Voltage, Temperature)-robust reference current comprising:
a reference current mirror including: a 1-st transistor, a 2-nd transistor, and a 3-rd transistor, wherein each of 1-st terminals of each of the 1-st transistor, the 2-nd transistor, and the 3-rd transistor is connected to a supply voltage providing part, wherein each of controlling terminals of each of the 1-st transistor, the 2-nd transistor, and the 3-rd transistor is provided with a current-controlling voltage, and wherein each of 2-nd terminals of each of the 1-st transistor, the 2-nd transistor, and the 3-rd transistor provides a reference current to each of a 1-st node, a 2-nd node, and a 3-rd node, wherein the reference current is generated according to the current-controlling voltage;
a current-controlling voltage generating part configured to generate the current-controlling voltage which allows the reference current to be corresponding to a specific temperature coefficient according to conditions of each of a reference voltage for adjusting a temperature coefficient fed through a 1-st input end of the current-controlling voltage generating part and a comparison voltage for adjusting the temperature coefficient fed through a 2-nd input end of the current-controlling voltage generating part;
a reference voltage generating part for adjusting the temperature coefficient configured to generate the reference voltage for adjusting the temperature coefficient, wherein the reference voltage is used for adjusting the temperature coefficient of the reference current according to the reference current fed through the 1-nd node;
a PTAT (Proportion To Absolute Temperature)-characteristics current acquiring part, which is connected to the 2-nd node, for allowing the reference current to have PTAT-characteristics in case the 2-nd node is connected to the 2-nd input end of the current-controlling voltage generating part;
a CTAT (Complementary To Absolute Temperature)-characteristics current acquiring part, which is connected to the 3-rd node, for allowing the reference current to have CTAT-characteristics in case the 3-rd node is connected to the 2-nd input end of the current-controlling voltage generating part; and
a comparison voltage generating part for adjusting the temperature coefficient, which is connected between the 2-nd node and the 3-rd node, wherein the comparison voltage generating part is configured to generate the comparison voltage to be used for adjusting the temperature coefficient of the reference current through an internal division of a 1-st voltage and a 2-nd voltage by using a specific weight value, wherein the specific weight value corresponding to the specific temperature coefficient of the reference current is determined by referring to the 1-st voltage of the 2-nd node caused by the PTAT-characteristics current acquiring part and the 2-nd voltage of the 3-rd node caused by the CTAT-characteristics current acquiring part.

2. The apparatus for generating the PVT-robust reference current of claim 1, wherein, on condition that (i) a full range of temperatures to be used has been divided into a 1-st sub-range and a 2-nd sub-range based on a specific temperature which is a temperature for allowing each of reference currents to have a same value over all of temperature coefficients, wherein the specific temperature is determined according to a ratio of a 1-st resistance value of a 1-st resistor included in the PTAT-characteristics current acquiring part and a 2-nd resistance value of a 2-nd resistor included in the CTAT-characteristics current acquiring part and (ii) a 1-st temperature coefficient and a 2-nd temperature coefficient have been determined, wherein the 1-st temperature coefficient makes a current-fluctuation ratio of the reference current according to a temperature change within the 1-st sub-range be the smallest, and wherein the 2-nd temperature coefficient makes a current-fluctuation ratio of the reference current according to a temperature change within the 2-nd sub-range be the smallest, the comparison voltage generating part for adjusting the temperature coefficient (i) selects a specific sub-range between the 1-st sub-range and the 2-nd sub-range by referring to a difference between the 1-st voltage and the 2-nd voltage, and (ii) performs the internal division of the 1-st voltage and the 2-nd voltage by using the specific weight value corresponding to the specific temperature coefficient selected between the 1-st temperature coefficient and the 2-nd temperature coefficient, wherein the specific temperature coefficient is determined according to the specific sub-range.

3. The apparatus for generating the PVT-robust reference current of claim 2, wherein the comparison voltage generating part for adjusting the temperature coefficient includes:
a comparator configured to output a control signal by comparing the 1-st voltage with the 2-nd voltage;
a multiplexer configured to output the specific weight value selected between a 1-st weight value and a 2-nd weight value according to the control signal, wherein the 1-st weight value is set to be corresponding to the 1-st temperature coefficient and the 2-nd weight value is set to be corresponding to the 2-nd temperature coefficient;
a row-column decoder configured to output a row-address signal and a column-address signal by referring to the specific weight value; and
an RDAC (resistive digital-to-analog converter) configured to output the comparison voltage used for adjusting the temperature coefficient of the reference current through the internal division of the 1-st voltage and the 2-nd voltage by using the specific weight value between the 2-nd node and the 3-rd node, according to the row-address signal and the column-address signal.

4. The apparatus for generating the PVT-robust reference current of claim 3, wherein the comparator has hysteresis characteristics.

5. The apparatus for generating the PVT-robust reference current of claim 1, further comprising: a reference current-outputting part which includes a 4-th transistor,
wherein a 1-st terminal of the 4-th transistor is connected to the supply voltage providing part, wherein the reference current generated by the reference current mirror is copied according to the current-controlling voltage fed to a controlling terminal of the 4-th transistor, and wherein the copied-reference current is outputted through a 2-nd terminal of the 4-th transistor.

6. The apparatus for generating the PVT-robust reference current of claim 1, wherein the reference voltage generating part for adjusting the temperature coefficient includes a 5-th transistor, wherein (i) a 1-st terminal of the 5-th transistor is connected to the 1-st node and (ii) a controlling terminal of the 5-th transistor and a 2-nd terminal of the 5-th transistor are connected to a ground line.

7. The apparatus for generating the PVT-robust reference current of claim 6, wherein the 5-th transistor is a bipolar transistor, wherein (i) an emitter terminal of the 5-th transistor is connected to the 1-st node and (ii) a base terminal of the 5-th transistor and a collector terminal of the 5-th transistor are connected to the ground line.

8. The apparatus for generating the PVT-robust reference current of claim 1, wherein the PTAT-characteristics current acquiring part includes a 1-st resistor and a 6-th transistor, wherein one end of the 1-st resistor is connected to the 2-nd node, wherein a 1-st terminal of the 6-th transistor is connected to an opposite end of the 1-st resistor, and wherein a controlling terminal of the 6-th transistor and a 2-nd terminal of the 6-th transistor are connected to a ground line.

9. The apparatus for generating the PVT-robust reference current of claim 8, wherein the 6-th transistor is a bipolar transistor, wherein (i) an emitter terminal of the 6-th transistor is connected to the opposite end of the 1-st resistor and (ii) a base terminal of the 6-th transistor and a collector terminal of the 6-th transistor are connected to the ground line.

10. The apparatus for generating the PVT-robust reference current of claim 1, wherein the CTAT-characteristics current acquiring part includes a 2-nd resistor, wherein one end of the 2-nd resistor is connected to the 3-rd node and an opposite end of the 2-nd resistor is connected to a ground line.

11. The apparatus for generating the PVT-robust reference current of claim 1, wherein the current-controlling voltage generating part includes an amplifier, wherein the reference voltage for adjusting the temperature coefficient is inputted into an inverting end of the amplifier and the comparison voltage for adjusting the temperature coefficient is inputted into a non-inverting end of the amplifier, and wherein an output end of the amplifier is connected to each of the controlling terminals of each of the 1-st transistor, the 2-nd transistor, and the 3-rd transistor.

12. The apparatus for generating the PVT-robust reference current of claim 1, wherein each of the 1-st transistor, the 2-nd transistor, and the 3-rd transistor is a PMOS transistor, wherein each of gate terminals of each of the 1-st transistor, the 2-nd transistor, and the 3-rd transistor is connected to an output end of the current-controlling voltage generating part, wherein each of source terminals of each of the 1-st transistor, the 2-nd transistor, and the 3-rd transistor is connected to the supply voltage providing part, and wherein each of drain terminals of each of the 1-st transistor, the 2-nd transistor, and the 3-rd transistor is connected to each of the 1-st node, the 2-nd node, and the 3-rd node.
